(19) United States
(12) Patent Application Publication
(10) Pub. No.: US 2007/0102719 A1
(43) Pub. Date: May 10, 2007

(54) Light emitting diode

(75) Inventor: Guo-Han Yue, ShenZhen (CN)

Correspondence Address: MORRIS MANNING MARTIN LLP, 3343 PEACHTREE ROAD, NE, 1600 ATLANTA FINANCIAL CENTER, ATLANTA, GA, 30326, US

(73) Assignee: HON HAI Precision Industry CO., LTD., Tu-Cheng City (TW)

(21) Appl. No.: 11/518,797

(22) Filed: Sep. 11, 2006

(30) Foreign Application Priority Data
Nov. 10, 2005 (CN) 200510101206.4

(51) Int. Cl. H01L 33/00

(52) U.S. Cl. 257/98

(57) ABSTRACT

A light emitting diode (10, 20, 30, 40) includes an illuminant element (12) and a package (14, 24, 34, 44). The illuminant element defines an optical axis (OO′, O₁O₁′, O₂O₂′, O₃O₃′). The package has a transparent surface (141, 241, 341, 441) oblique to the optical axis. The illuminant element is disposed inside the package. Light illuminated by the illuminant element emits from the light emitting diode via the transparent surface.

### TECHNICAL FIELD

The present invention relates to light emitting assemblies such as those used for backlight modules, and particularly to a light emitting diode (LED) that can be used for a backlight module of a liquid crystal display (LCD) device.

### BACKGROUND

Nowadays, liquid crystal materials are widely utilized in various liquid crystal displays that have different sizes for different applications such as televisions (TVs), liquid crystal projectors, mobile telephones, personal digital assistants (PDAs), etc. Since liquid crystals themselves cannot emit light, a light source must be utilized to illuminate the liquid crystals for displaying of images. The light source can be ambient light or an accompanying artificial light source. An accompanying artificial light source is also commonly known as a backlight source, since it is usually positioned behind a corresponding liquid crystal panel. A combination of components behind the liquid crystal panel, including the light source and a light guide plate, is generally referred to as a backlight module.

Typically, cold cathode fluorescent lamps (CCFLs) and light emitting diodes (LEDs) are employed as light sources in various backlight devices. However, backlight devices employing CCFLs as light sources have the disadvantages of high energy consumption, low optical uniformity, and poor purity of white light. In addition, after being repeatedly used over time, the brightness of a CCFL becomes degraded and a color of light emitted by the CCFL tends to shift. In general, CCFLs have a service life of about 15,000 to 25,000 hours. Furthermore, CCFLs only cover 75 percent of color space as defined by the National Television Standards Committee (NTSC). Therefore, CCFLs cannot satisfy high quality liquid crystal display requirements.

Unlike CCFLs, high power LEDs can cover as much as 105 percent of color space as defined by the NTSC. In addition, these LEDs have other advantages such as low energy consumption, long service life, and so on. Therefore, high power LEDs are better suited for high quality liquid crystal displays.

A typical LED has a transparent emitting surface that is perpendicular to an optical axis thereof. When the LED is applied in a conventional backlight module, an amount of light rays parallel to the optical axis emits from the transparent surface into a light guide plate. The light guide plate has an incident surface and an emitting surface adjoining the incident surface, and the light rays enter the light guide plate through the incident surface. The light rays are generally perpendicular to the incident surface of the light guide plate, and pass through the light guide plate parallel to the optical axis. Some of the light rays exit the light guide plate at surfaces thereof other than the emitting surface, and are reflected back into the light guide plate by suitable reflective means. For example, a reflective sheet can be provided at a surface of the light guide plate opposite to the incident surface, and a reflective mask can be provided around the LED adjacent to the incident surface. Much light energy may be wasted if a significant amount of light rays is reflected by the reflective sheet and the reflective mask. In addition, some light rays leak out from the light guide plate through gaps between the light guide plate and the reflective sheet. In certain cases, the amount of leakage may be significant. Therefore, the brightness of light provided by the backlight module may be substantially reduced.

What is needed, therefore, is a light emitting diode that can overcome the above-described disadvantages.

### SUMMARY

A light emitting diode that can be used for a backlight module is provided. The light emitting diode includes an illuminant element and a package. The illuminant element defines an optical axis. The package has a transparent surface oblique to the optical axis. The illuminant element is disposed inside the package. Light illuminated by the illuminant element emits from the light emitting diode via the transparent surface.

Other advantages and novel features will become more apparent from the following detailed description of preferred embodiments when taken in conjunction with the accompanying drawings.

### BRIEF DESCRIPTION OF THE DRAWINGS

The components in the drawings are not necessarily to scale, the emphasis instead being placed upon clearly illustrating the principles of the present light emitting diode. Moreover, in the drawings, like reference numerals designate corresponding parts throughout the several views.

FIG. 1 is an isometric view of a light emitting diode according to a first preferred embodiment of the present invention.

FIG. 2 is a cross-sectional view taken along line II-II of FIG. 1.

FIG. 3 is a left side view of the light emitting diode of FIG. 1 next to a side of a light guide plate, showing essential light paths.

FIG. 4 is a right side view of a light emitting diode according to a second preferred embodiment of the present invention.

FIG. 5 is a left side view of the light emitting diode of FIG. 4 next to a side of a light guide plate, showing essential light paths.

FIG. 6 is an isometric view of a light emitting diode according to a third preferred embodiment of the present invention.

FIG. 7 is a right side view of the light emitting diode of FIG. 6.

FIG. 8 is an isometric view of a light emitting diode according to a fourth preferred embodiment of the present invention.

FIG. 9 is a right side view of the light emitting diode of FIG. 8.

FIG. 10 is a directivity graph for the light emitting diodes of FIG. 6 and FIG. 8.

### DETAILED DESCRIPTION OF PREFERRED EMBODIMENTS

Reference will now be made to the drawings to describe preferred embodiments of the present light emitting diode in detail.

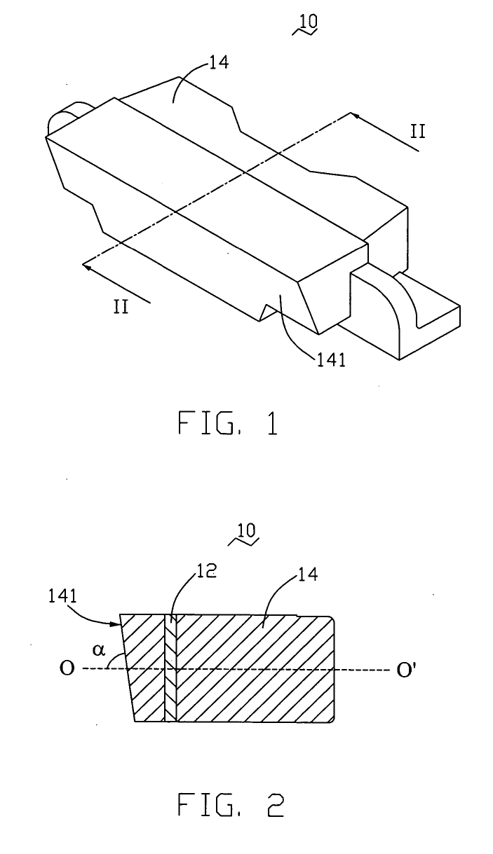

Referring to FIG. 1 and FIG. 2, a light emitting diode 10 of a first preferred embodiment of the present invention includes an illuminant element 12 and a package 14. The illuminant element 12 is an illuminant chip defining an optical axis OO′. The illuminant element 12 is disposed inside the package 14. The package 14 is made of transparent material such as glass. The package 14 has a flat transparent surface 141, and other surfaces that are configured to in effect be non-transmissive. Thereby, light rays generated by the illuminant element 12 are emitted out of the light emitting diode 10 via the transparent surface 141 only. For example, reflective sheets may be disposed adjacent to the other surfaces, to prevent light rays from emitting thereout. An angle α defined by the transparent surface 141 relative to the optical axis OO′ is configured to be in the range from greater than 0 degrees to less than 90 degrees. The angle α is 82 degrees in the illustrated embodiment. That is, the transparent surface 141 is slanted such that a topmost portion thereof is most protrusive.

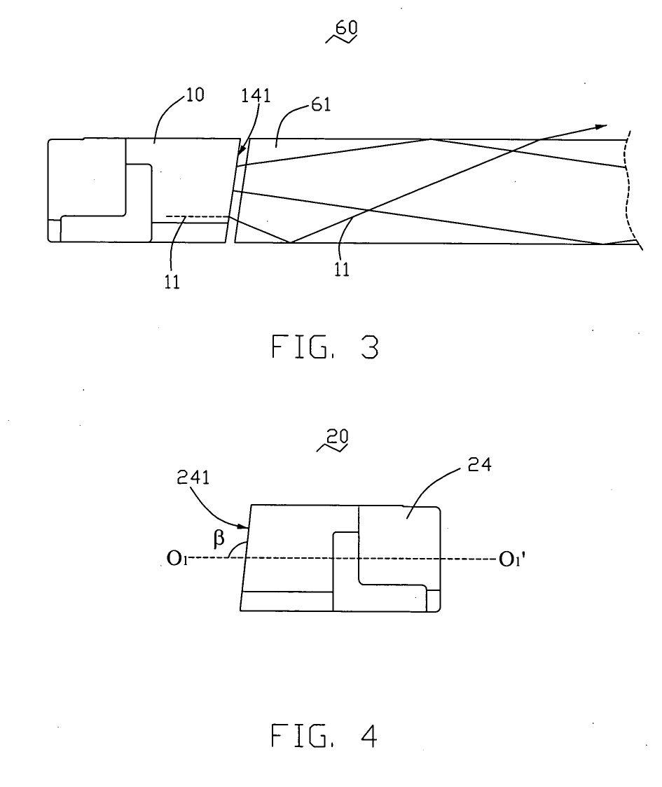

Referring to FIG. 3, the light emitting diode 10 can be positioned next to a light guide plate 61 in a backlight device 60. Light 11 transmitting within the light emitting diode 10 which is parallel to the optical axis OO′ is refracted by the transparent surface 141 and then emits from the transparent surface 141. Further, because the transparent surface 141 is oblique to the optical axis OO′, the refracted light 11 emits from the transparent surface 141 at angles that are oblique to the optical axis OO′. The light 11 then enters the light guide plate 61. The light 11 transmits and/or reflects inside the light guide plate 61 and then emits from a top emitting surface of the light guide plate 61. Because the light 11 emits from the light emitting diode 10 at angles that are oblique to the optical axis OO′ before the light 11 enters the light guide plate 61, the light 11 transmits and/or reflects inside the light guide plate 61 with relatively little need for reflection by any reflective elements provided around the light guide plate 61. In particular, there may be little or no need to provide a reflective element adjacent to a surface of the light guide plate 61 which is opposite to the transparent surface 141. Thus, relatively little light energy is wasted in the process of passage of the light 11 within the light guide plate 61 and out through the emitting surface thereof. Accordingly, a utilization rate of all light emitted by the light emitting diode 10 is correspondingly high, whereby the backlight device 60 utilizing the light emitting diode 10 can provide high brightness.

Referring to FIG. 4, a light emitting diode 20 of a second preferred embodiment of the present invention is substantially the same as the light emitting diode 10 of the first preferred embodiment. However, in the light emitting diode 20, a transparent surface 241 of a package 24 is slanted such that a bottommost portion thereof is most protrusive. That is, an angle β defined by the transparent surface 241 relative to an optical axis O₁O₁′ is configured to be in the range from greater than 90 degrees to less than 180 degrees. The angle β is 98 degrees in the illustrated embodiment.

Also referring to FIG. 5, the light emitting diode 20 can be positioned next to a light guide plate 71 in a backlight device 70. Light 21 transmitting within the light emitting diode 20 which is parallel to the optical axis O₁O₁′ is refracted by the transparent surface 241 and then emits from the transparent surface 241. Further, because the transparent surface 241 is oblique to the optical axis O₁O₁′, the refracted light 21 emits from the transparent surface 241 at angles that are oblique to the optical axis O₁O₁′. The light 21 then enters the light guide plate 71. The light 21 transmits and/or reflects inside the light guide plate 71 and then emits from a top emitting surface of the light guide plate 71. The characteristics of transmission and/or reflection of the light 21 inside the light guide plate 71 are similar to the characteristics of transmission and/or reflection of the light 11 inside the light guide plate 61 described above. Thus, relatively little light energy is wasted in the process of passage of the light 21 within the light guide plate 71 and out through the emitting surface thereof. Accordingly, a utilization rate of all light emitted by the light emitting diode 20 is correspondingly high, whereby the backlight device 70 utilizing the light emitting diode 20 can provide high brightness.

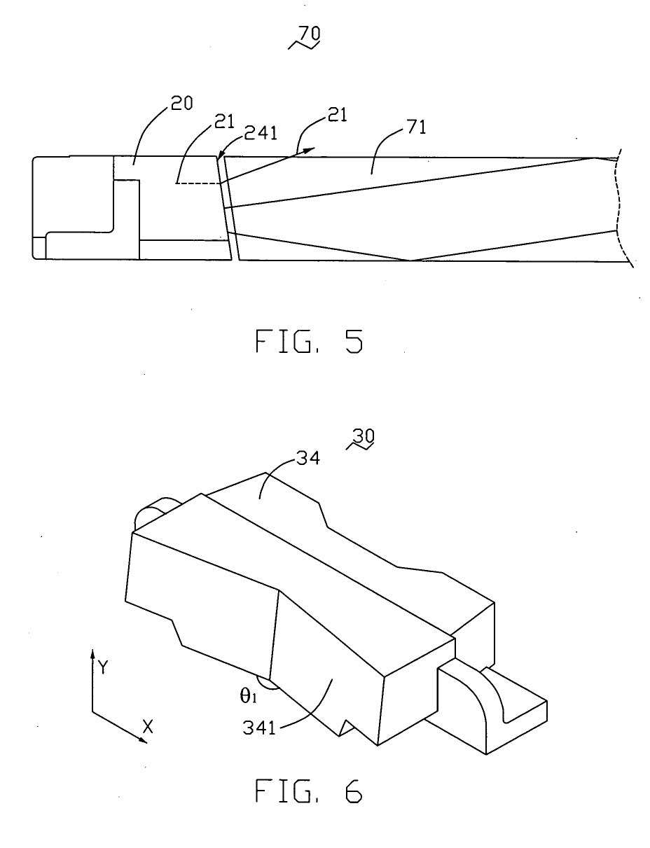

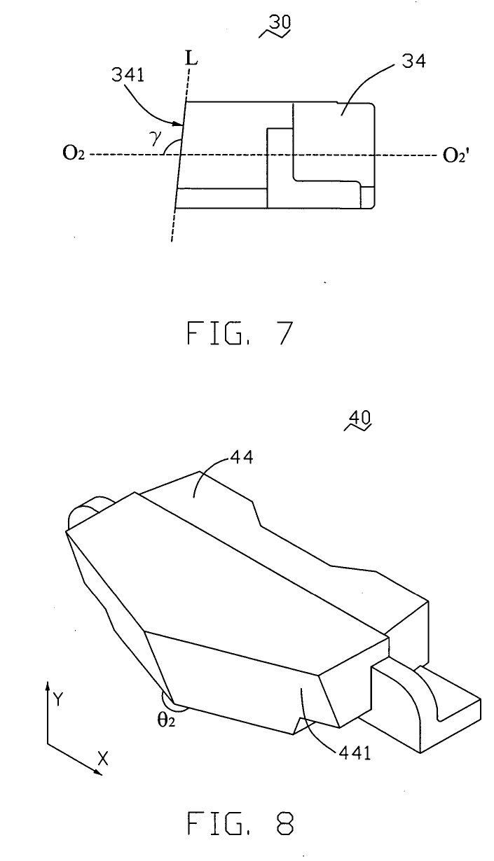

Referring to FIG. 6 and FIG. 7, a light emitting diode 30 of a third preferred embodiment of the present invention is substantially the same as the light emitting diode 10 of the first preferred embodiment. However, in the light emitting diode 30, a transparent surface 341 of a package 34 is an indentation surface formed by two flat surface portions. That is, the transparent surface 341 is generally V-shaped. An angle θ₁ defined between the two flat surface portions of the transparent surface 341 is configured to be in the range from 90 degrees to less than 180 degrees. The angle θ₁ is 164 degrees in the illustrated embodiment. The light emitting diode 30 defines an optical axis O₂O₂′. An angle γ defined by the transparent surface 341 relative to the optical axis O₂O₂′ is configured to be in the range from greater than 90 degrees to less than 180 degrees. That is, the transparent surface 341 is slanted such that a bottommost portion thereof is most protrusive. In an alternative embodiment, the transparent surface 341 can be slanted such that a topmost portion thereof is most protrusive. In such case, the angle γ is in the range from greater than 0 degrees to less than 90 degrees.

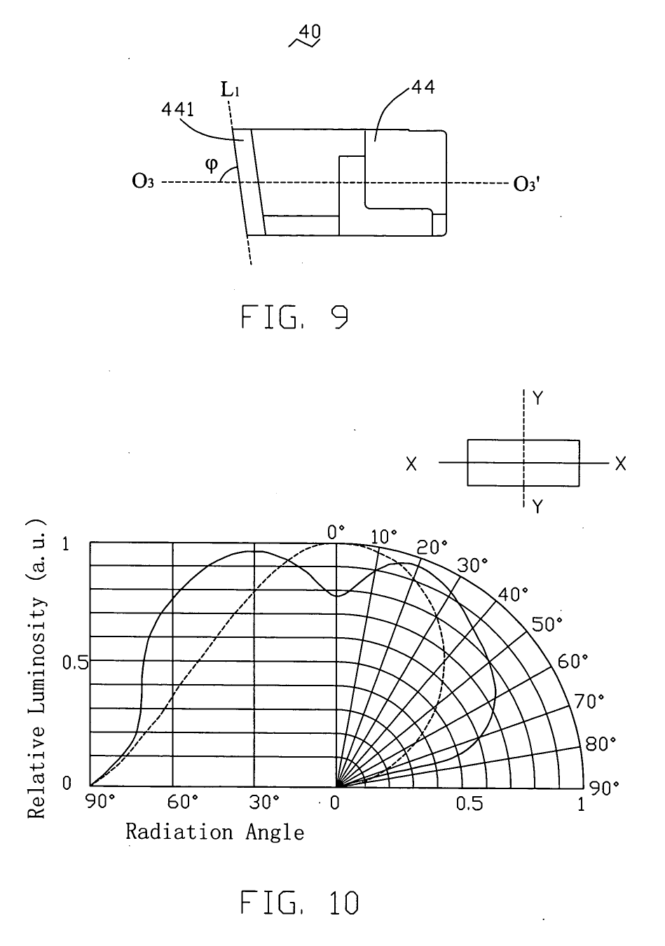

Referring to FIG. 8 and FIG. 9, a light emitting diode 40 of a fourth preferred embodiment of the present invention is substantially the same as the light emitting diode 10 of the first preferred embodiment. However, in the light emitting diode 40, a transparent surface 441 of a package 44 is a protrusive surface formed by two flat surface portions. That is, the transparent surface 441 is generally V-shaped. An angle θ₂ defined between the two flat surface portions of the transparent surface 441 is configured to be in the range from greater than 180 degrees to 300 degrees. The angle θ₂ is 196 degrees in the illustrated embodiment. The light emitting diode 40 defines an optical axis O₃O₃′. An angle φ defined by the transparent surface 341 relative to the optical axis O₃O₃′ is configured to be in the range from greater than 0 degrees to less than 90 degrees. That is, the transparent surface 441 is slanted such that a topmost portion thereof is most protrusive. In an alternative embodiment, the transparent surface 441 can be slanted such that a bottommost portion thereof is most protrusive. In such case, the angle φ is in the range from greater than 90 degrees to less than 180 degrees.

FIG. 10 shows a directivity graph for each of the light emitting diodes 30, 40 when the ambient temperature is 25 degrees Celsius and a forward current (I_{F}) applied to each of the light emitting diodes 30, 40 is 20 milliamperes. That is, a light brightness distribution for each of the light emitting diodes 30, 40 is shown. The solid line shows a light brightness distribution in an X-X direction. The dashed line shows a light brightness distribution in a Y-Y direction. It can be seen from the solid line that light brightness is high. Further, the solid line shows that a difference in brightness between an area near the optical axis O₂O₂′, O₃O₃′ and an area far from the optical axis O₂O₂′, O₃O₃′ in an X-X direction is small. That is, the uniformity of illumination provided by the light emitting diodes 30, 40 is high.

In summary, light rays transmitting within the light emitting diodes 10, 20, 30, 40 which are parallel to the optical axes OO′, O₁O₁′, O₂O₂′, O₃O₃′ emit from the light emitting diodes 10, 20, 30, 40 at angles that are oblique to the optical axes OO′, O₁O₁′, O₂O₂′, O₃O₃′. In exemplary use of the light emitting diodes 10, 20, 30, 40, the light rays then enter the light guide plates. The light rays transmit and/or reflect inside the light guide plates and then emit from top emitting surfaces of the light guide plates. Relatively little light energy is wasted in the processes of passage of the light rays within the light guide plates and out through the emitting surfaces thereof. Accordingly, a utilization rate of all light rays emitted by the light emitting diodes 10, 20, 30, 40 is correspondingly high, whereby the backlight devices utilizing the light emitting diodes 10, 20, 30, 40 can provide high brightness.

In alternative embodiments, besides the flat transparent surfaces 141, 241 and the V-shaped transparent surfaces 341, 441, a transparent surface having another shape can be configured. Examples include an indentation surface formed by three or more flat surface portions, a protrusive surface formed by three or more flat surface portions, a curved or concave indentation surface, and a curved or convex protrusive surface. Further, the illuminant element 12 may be in the form of a linear light source or a point light source.

Finally, while the present invention has been described with reference to particular embodiments, the description is illustrative of the invention and is not to be construed as limiting the invention. Therefore, various modifications can be made to the embodiments by those skilled in the art without departing from the true spirit and scope of the invention as defined by the appended claims and equivalents thereof.

What is claimed is:

1. A light emitting diode, comprising:
an illuminant element defining an optical axis; and
a package having a transparent surface oblique to the optical axis, the illuminant element disposed inside the package, light illuminated by the illuminant element emitting out of the light emitting diode via the transparent surface.

2. The light emitting diode according to claim 1, wherein the package is made of transparent material.

3. The light emitting diode according to claim 1, wherein the transparent surface is a flat surface.

4. The light emitting diode according to claim 3, wherein an angle defined by the transparent surface relative to the optical axis is configured to be in the range from greater than 0 degrees to less than 90 degrees.

5. The light emitting diode according to claim 3, wherein an angle defined by the transparent surface relative to the optical axis is configured to be in the range from greater than 90 degrees to less than 180 degrees.

6. The light emitting diode according to claim 1, wherein the transparent surface is an indentation surface.

7. The light emitting diode according to claim 6, wherein the transparent surface is formed by two flat surface portions and is generally V-shaped.

8. The light emitting diode according to claim 7, wherein an angle defined by the transparent surface relative to the optical axis is in the range from greater than 90 degrees to less than 180 degrees or in the range from greater than 0 degrees to less than 90 degrees.

9. The light emitting diode according to claim 7, wherein an angle defined between the two flat surface portions of the transparent surface is configured to be in the range from 90 degrees to less than 180 degrees.

10. The light emitting diode according to claim 1, wherein the transparent surface is a protrusive surface.

11. The light emitting diode according to claim 10, wherein the transparent surface is formed by two flat surface portions and is generally V-shaped.

12. The light emitting diode according to claim 11, wherein the an angle defined by the transparent surface relative to the optical axis is in the range from greater than 90 degrees to less than 180 degrees or in the range from greater than 0 degrees to less than 90 degrees.

13. The light emitting diode according to claim 11, wherein an angle defined between the two flat surface portions of the transparent surface is configured to be in the range from greater than 180 degrees to 300 degrees.
